(19) United States
(12) Patent Application Publication
(10) Pub. No.: US 2011/0013347 A1
(43) Pub. Date: Jan. 20, 2011

(54) ELECTRONIC APPARATUS

(75) Inventor: Kazuyuki KINJOU, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/768,545

(22) Filed: Apr. 27, 2010

(30) Foreign Application Priority Data
Jul. 15, 2009 (JP) 2009-166857

(51) Int. Cl. H05K 5/00

(52) U.S. Cl. 361/679.01

(57) ABSTRACT

According to one embodiment, an electronic apparatus includes a housing formed of a metal and including an opening part and a first overlap margin portion neighboring the opening part, a cover formed of a resin and including a second overlap margin portion lying over the first overlap margin portion, the cover covering the opening part, a screw, and a film. The screw fixes the first overlap margin portion of the housing and the second overlap margin portion of the cover. The film covers an outer surface of the housing, an outer surface of the cover and a part of the screw.

### CROSS-REFERENCE TO RELATED APPLICATIONS

This application is based upon and claims the benefit of priority from Japanese Patent Application No. 2009-166857, filed Jul. 15, 2009, the entire contents of which are incorporated herein by reference.

### BACKGROUND

1. Field

One embodiment of the present invention relates to an electronic apparatus including an antenna cover.

2. Description of the Related Art

Jpn. Pat. Appln. KOKAI Publication No. 2008-3714 discloses an electronic apparatus including an antenna cover. This electronic apparatus comprises a metallic housing, an opening part which is provided in the housing, and an antenna cover which covers the opening part. The housing has a through-hole portion adjacent to the opening part. In addition, the antenna cover has, at its end portion, a projection for welding, which is to be inserted in the through-hole portion.

In this electronic apparatus, in the state in which the projection for welding is inserted in the through-hole portion, the projection for welding is heated and deformed so as to be flattened. Thereby, the antenna cover is fixed to the opening part of the housing.

When the antenna cover is fixed to the housing by using welding, as described above, if the projection for welding is heated excessively, the projection for welding, in come cases, drops off from the body part of the antenna cover. Under the circumstances, the fixing of the antenna cover has required the skill of workers.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view showing a portable computer according to a first embodiment;

FIG. 2 is an exemplary rear view of a second case of the portable computer shown in FIG. 1;

FIG. 3 is an exemplary rear view of a display unit of the portable computer shown in FIG. 1;

FIG. 4 is an exemplary side view showing the state in which the display unit of the portable computer shown in FIG. 1 is detached;

FIG. 5 is an exemplary longitudinal cross-sectional view of a region, encircled by F3, of the display unit of the portable computer shown in FIG. 4;

FIG. 6 is an exemplary longitudinal cross-sectional view of a display unit of a portable computer according to a second embodiment;

FIG. 7 is an exemplary longitudinal cross-sectional view of a display unit of a portable computer according to a third embodiment;

FIG. 8 is an exemplary longitudinal cross-sectional view of a display unit of a portable computer according to a fourth embodiment;

FIG. 9 is an exemplary longitudinal cross-sectional view of a display unit of a portable computer according to a fifth embodiment; and

FIG. 10 is an exemplary longitudinal cross-sectional view of a display unit of a portable computer according to a sixth embodiment.

### DETAILED DESCRIPTION

Various embodiments according to the invention will be described hereinafter with reference to the accompanying drawings. In general, according to one embodiment of the invention, an electronic apparatus includes a housing formed of a metal and including an opening part and a first overlap margin portion neighboring the opening part; a cover formed of a resin and including a second overlap margin portion lying over the first overlap margin portion, the cover covering the opening part; a screw; and a film. The screw fixes the first overlap margin portion of the housing and the second overlap margin portion of the cover. The film covers an outer surface of the housing, an outer surface of the cover and a part of the screw.

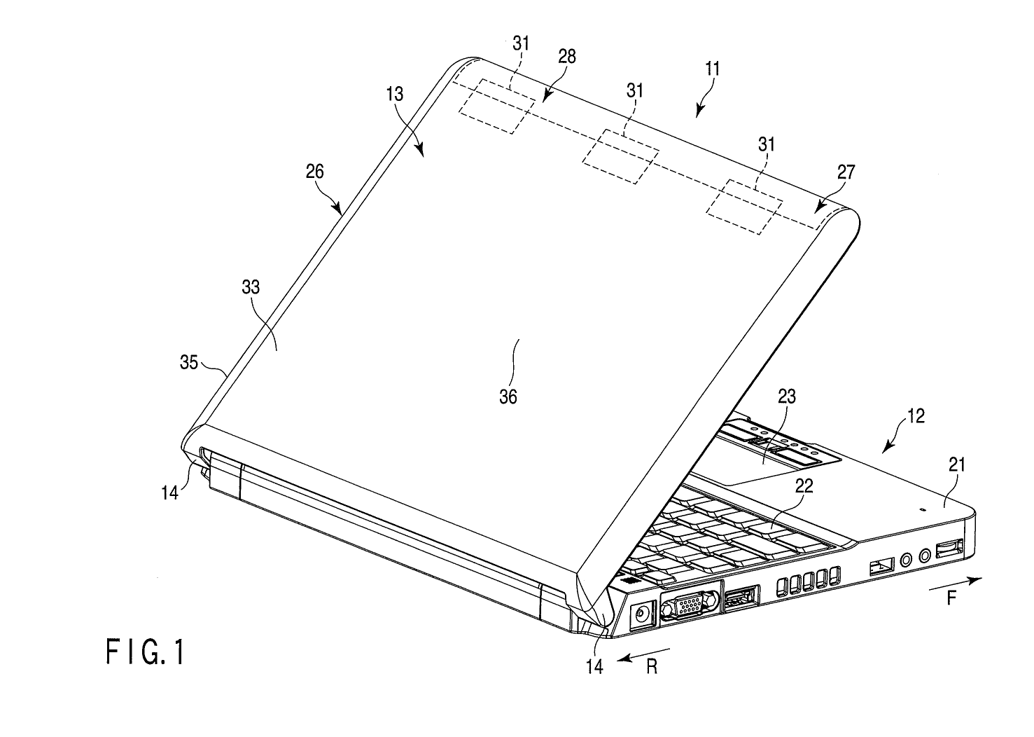

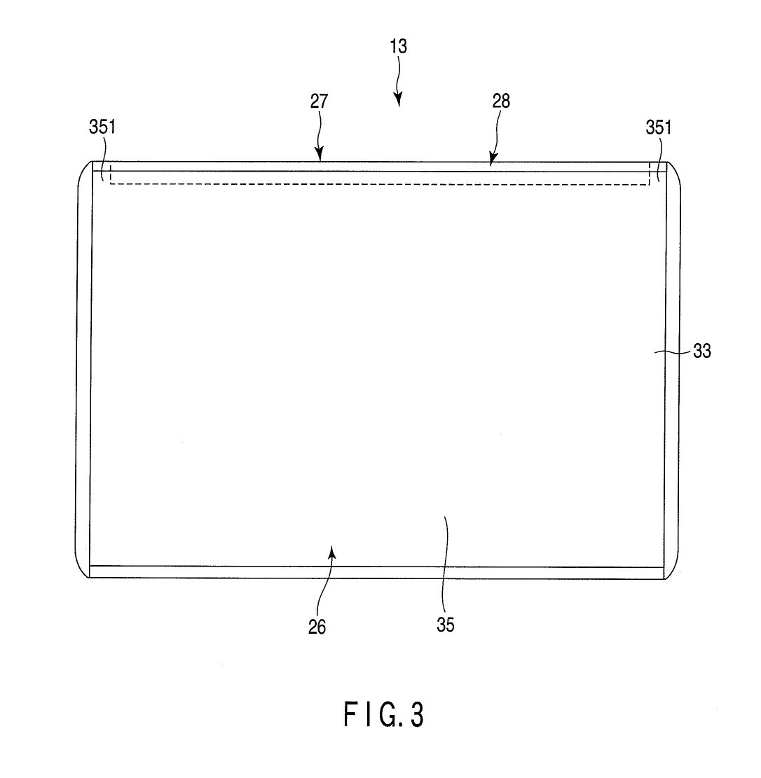

A first embodiment of an electronic apparatus according to the invention will now be described with reference to FIG. 1 to FIG. 5. In this specification, the near side to the user (that is, user side) is defined as front F, the far side from the user is rear R, the left-hand side of the user is left, the right-hand side of the user is right, the upper side from the user's position is up, and the lower side from the user's position is down.

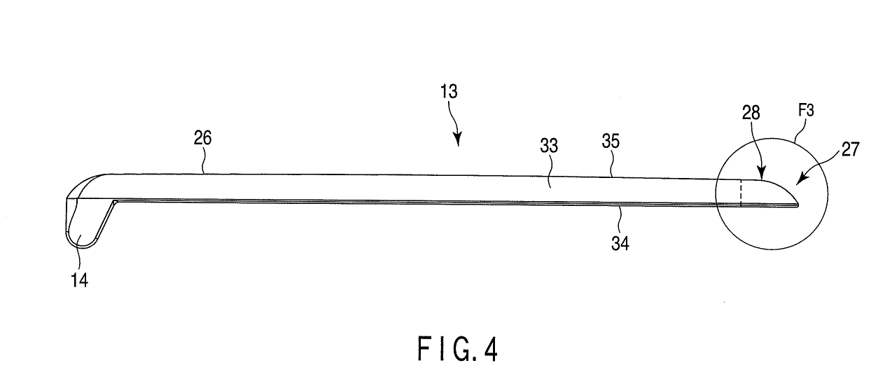

As shown in FIG. 1, a portable computer 11, which is an example of the electronic apparatus, comprises a main body unit 12, a display unit 13, and hinge portions 14 which are provided between the main body unit 12 and the display unit 13. The hinge portions 14 rotatably support the display unit 13. The display unit 13 is rotatable between a first position where the display unit 12 stands up, relative to the main body unit, as shown in FIG. 4, and a second position where the display unit 13 covers the main body unit 12 in parallel with the main body unit 12.

As shown in FIG. 1, the main body unit 12 comprises a main body cabinet 21 which is formed of, for example, a metal; a keyboard 22 and a touch pad 23, which are attached to the upper surface of the main body cabinet 21; and a printed circuit board 24 which is accommodated within the main body cabinet 21. The printed circuit board 24 includes circuit components, such as a CPU, which are mounted thereon. The main body cabinet 21 is formed, for example, by magnesium die-cast using a magnesium alloy. Alternatively, the main body cabinet 21 may be formed of, e.g. an aluminum alloy.

As shown in FIG. 1 to FIG. 5, the display unit 13 comprises a display 25; a display cabinet 26 surrounding the periphery of the display 25; an opening part 27 which is provided on the display cabinet 26; a cover 28 covering the opening part 27; a plurality of antennas 31 provided within the display cabinet 26; a screw 32 for fixing a second case 35 of the display cabinet 26 and the cover 28; and a light-blocking film 33 which is provided on the outer surface of the display cabinet 26 and the outer surface of the cover 28. In the present embodiment, a liquid crystal display is mounted as an example of the display 25. In the present invention, the concept of the term “housing” includes the main body cabinet 21 and the display cabinet 26.

The plural antennas 31 (antenna circuit boards) are adaptive to various communication systems, such as Bluetooth (trademark), wireless LAN, wireless WAN, WiMAX, UWB and GPS, and various mobile phone systems, such as 3 G and 3.5 G. As shown in FIG. 1, the plural antennas 31 are disposed, for example, in a juxtaposed fashion at positions spanning between the second case 35 of the display cabinet 26 (to be described later) and the cover 28. The plural antennas 31 are fixed from the inside of the second case 35 and cover 28 at the positions spanning between the second case 35 and the cover 28 by means of, e.g. adhesion. In FIG. 1, three antennas 31 are shown. However, the number of antennas 31 is not limited to three, and the number may be two or less, or four or more.

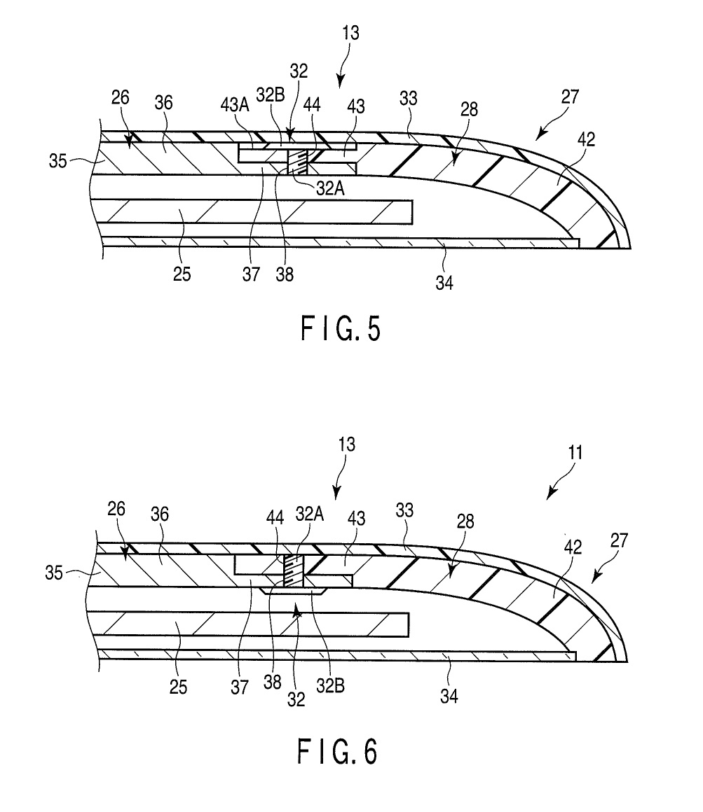

As shown in FIG. 4 and FIG. 5, the display cabinet 26 comprises a first case 34 which covers the front surface of the display 25, and the second case 35 which covers the rear surface of the display 25. The first case 34 is formed of, for example, a transparent glass in a flat plate shape. Alternatively, the first case 34 may be formed of a rectangular picture-frame shape so as to cover only the outer peripheral part of the display 25. Besides, the first case 34 may be formed of, for example, an acrylic synthetic resin in a flat plate shape.

The second case 35 is formed by magnesium die-cast using a metallic material such as a magnesium alloy. The second case 35, however, is not limited to the case 35 which is formed by casting a magnesium alloy. For example, the second case 35 may be formed by aluminum die-cast using an aluminum alloy, or may be formed by pressing and bending a plate material of, e.g. an aluminum alloy.

The second case 35 includes a main body portion 36. The main body portion 36 has a flat plate shape as a whole. The outer peripheral edge portion of the main body portion 36 has such a shape as to gently rise in an arcuate shape along the sides except the side neighboring the cover 28. As shown in FIG. 5, the second case 35 further includes a first overlap margin portion 37 which is provided at a position neighboring the opening part 27. The first overlap margin portion 37 is provided with a first through-hole portion 38 with a circular shape. A female thread, with which a shaft portion 32A of the screw 32 is fixedly engaged, is formed on the inner surface of the first through-hole portion 38.

The cover 28 comprises a cover portion 42 which covers the opening part 27; a second overlap margin portion 43 which is so provided as to project from the cover portion 42 and to lie over the first overlap margin portion 37; and a recess portion 43A which is provided on the second overlap margin portion 43 at a position opening to the outside. The second overlap margin portion 43 lies over the first overlap margin portion 37 of the second case 35 and is fixed to the first overlap margin portion 37. The second overlap margin portion 43 is provided with a second through-hole portion 44 with a circular shape. The diameter of the second through-hole portion 44 is substantially equal to, or slightly greater than, the diameter of the first through-hole portion 38. No female thread is formed on the inside of the second through-hole portion 44. The recess portion 43A is formed to be recessed from the outer surface of the cover 28 by a degree corresponding to the height of a head portion 32B of the screw 32.

The screw 32 comprises the shaft portion 32A which is inserted in the first through-hole portion 38 and second through-hole portion 44, and the head portion 32B which is provided at one end of the shaft portion 32A. The screw 32 fixes the first overlap margin portion 37 of the second case 35 and the second overlap margin portion 43 of the cover 28. The head portion 32B of the screw 32 is accommodated inside the recess portion 43A so that the head portion 32B of the screw 32 does not project from the surfaces of the second case 35 and cover 28.

The light-blocking film 33 is closely attached to the outer surface of the second case 35 and the outer surface of the cover 28, for example, by an IMF (In Mold Film) process. The light-blocking film 33 covers the outer surface of the second case 35, the outer surface of the cover 28, and a part of the screw 32, thereby adding decoration to these parts. Next, a description is given of the method of attaching the light-blocking film 33.

Prior to attaching the light-blocking film 33, an adhesive is coated on the back surface of the light-blocking film 33. Two kinds of adhesives are used for the adhesion of the light-blocking film 33. For example, an acrylic resin-based adhesive is coated on that region of the light-blocking film 33, which corresponds to the second case 35. On the other hand, for example, an epoxy-based adhesive is coated on that region of the light-blocking film 33, which corresponds to the cover 28. The second case 35 and the cover 28 are fixed in advance by the screw 32. The light-blocking film 33, the second case 35 and the cover 28 are placed within a vacuum/pressure forming machine, and are subjected to vacuum/pressure forming. Thereby, the outer surfaces of the second case 35, cover 28 and part of the screw 32 are covered in close contact with the light-blocking film 33, and the addition of decoration to the second case 35 and cover 28 is completed.

If the vacuum/pressure forming is performed by using two kinds of adhesives as in the present embodiment, the adhesion of the light-blocking film 33 to the second case 35 and cover 28, which are formed of different materials, is improved, compared to the case of the adhesion with one kind of adhesive. In the case of adding decoration to the surfaces of the second case 35 and cover 28 by other decoration-adding methods, there are cases in which the film 33 does not closely adhere up to an arcuate end portion of the cover 28. In the present embodiment, since the vacuum/pressure forming is used, the film 33 can surely be closely adhered up to the end face of the cover 28.

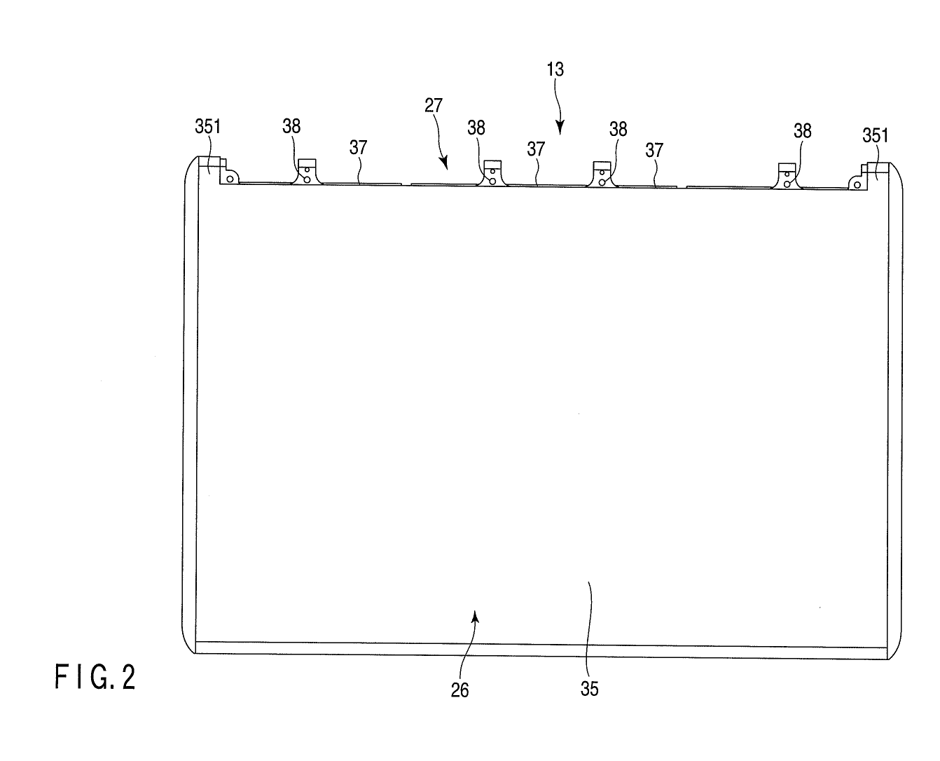

As shown in FIG. 2, the second case 35 of the present embodiment includes corner portions 351. Since the light-blocking film 33 spans the cover 28 and comes in close contact with the corner portions 351 at both ends of the second case 35, the cover 28 can be held at the mounting position of the second case 35.

According to the first embodiment, the portable computer 11 comprises a metallic housing including the opening part 27 and the first overlap margin portion 37 which neighbors the opening part 27; the resin-made cover 28 which includes the second overlap margin portion 43 lying over the first overlap margin portion 37, and covers the opening part 27; the screw 32 which fixes the first overlap margin portion 37 of the housing and the second overlap margin portion 43 of the cover 28; and the light-blocking film 33 covering the outer surface of the housing, the outer surface of the cover 28 and a part of the screw 32.

According to this structure, since the housing and the cover 28 can be fixed without using welding, it is possible to prevent a defective product from occurring due to dropping of a projection for welding, a failure of welding, etc. Accordingly, the yield of products can be improved with the simple structure using the screw 32. In addition, since the boundary part between the housing and the cover 28 and the part of the screw 32 can be hidden from view by the light-blocking film 33, the appearance of the product can be improved. Moreover, since the connection part between the housing and the cover 28 can be reinforced by the single light-blocking film 33, the strength of attachment of the cover 28 can be improved.

In this case, the second overlap margin portion 43 has the recess portion 43A which is recessed from the outer surface of the cover 28, and this recess portion 43A accommodates the head portion of the screw 32. According to this structure, the head portion 32B of the screw 32 does not project from the outer surfaces of the housing, cover 28 and second overlap margin portion 43, and the appearance of the electronic apparatus can be improved. In addition, since the head portion 32B of the screw 32 is prevented from projecting, the light-blocking film 33 is prevented from being easily broken at the position of the screw 32.

Next, referring to FIG. 6, a second embodiment of the electronic apparatus is described. A portable computer 11, which is an example of the electronic apparatus of the second embodiment, is different from the portable computer 11 of the first embodiment with respect to the direction of attachment of the screw 32. In the other parts, the second embodiment is common to the first embodiment. Thus, different parts are mainly described, and a description of the common parts is omitted, with these common parts being denoted by like reference numerals. The portable computer 11 has the same external appearance as in the first embodiment shown in FIG. 1.

In the second embodiment, the screw 32 is fixed from the inside of the display cabinet 26, and the head portion 32B is fixed to be positioned inside the display cabinet 26. The screw 32 comprises the shaft portion 32A which is inserted in the first through-hole portion 38 and second through-hole portion 44, and the head portion 32B which is provided at one end of the shaft portion 32A. The screw 32 fixes the first overlap margin portion 37 of the second case 35 and the second overlap margin portion 43 of the cover 28.

According to the second embodiment, even in the case where the direction of fixation of the screw 32 is reversed and the head portion 32B of the screw 32 is disposed inside the display cabinet 26, the yield of products can be improved with the simple structure using the screw 32. In addition, since the boundary part between the housing and the cover 28 and the part of the screw 32 can be hidden from view by the light-blocking film 33, the appearance of the product can be improved.

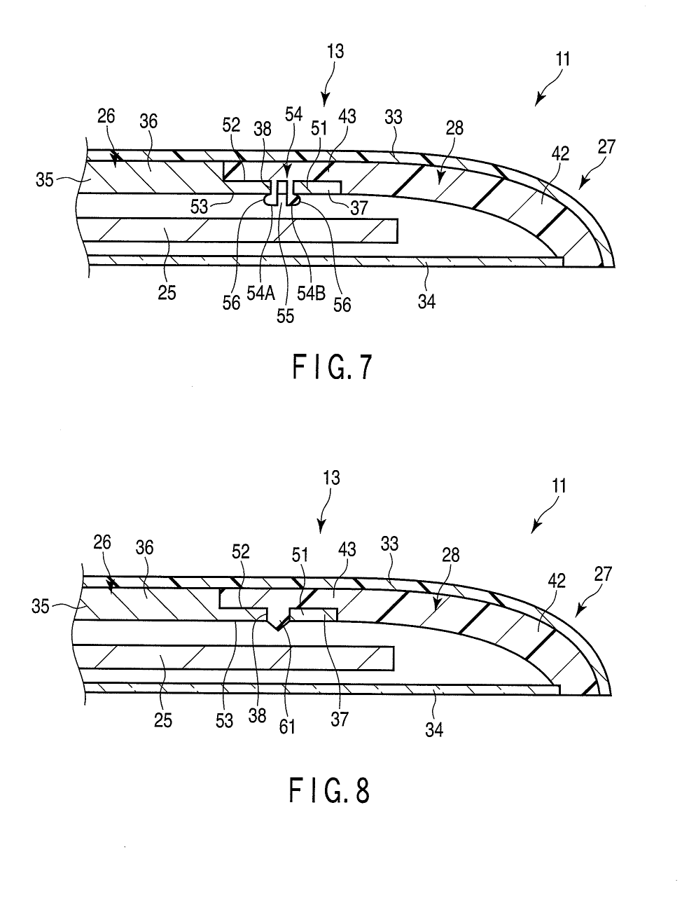

Next, referring to FIG. 7, a third embodiment of the electronic apparatus is described. A portable computer 11, which is an example of the electronic apparatus of the third embodiment, is different from the portable computer of the first embodiment in that a hook portion 54 is substituted for the screw 32. In the other parts, the third embodiment is common to the first embodiment. Thus, different parts are mainly described, and a description of the common parts is omitted, with these common parts being denoted by like reference numerals. The portable computer 11 has the same external appearance as in the first embodiment shown in FIG. 1.

The second case 35 includes a first overlap margin portion 37 which is provided at a position neighboring the main body portion 36 and opening portion 27. The first overlap margin portion 37 is provided with a circular through-hole portion 38 and an edge portion 51 which defines the periphery of the through-hole portion 38. The first overlap margin portion 37 has a first surface 52 which is opposed to the second overlap margin portion 43 of the cover 28, and a second surface 53 which is on a side opposite to the first surface 52.

The cover 28 comprises a cover portion 42 which covers the opening part 27; the second overlap margin portion 43 which is so provided as to project from the cover portion 42 and to lie over the first overlap margin portion 37; and the hook portion 54 which is provided in a manner to project from the second overlap margin portion 43. The second overlap margin portion 43 is laid over the first overlap margin portion 37. The hook portion 54 is passed through the through-hole 38.

The hook portion 54 has a cylindrical shape as a whole. The hook portion 54 is divided into a first portion 54A and a second portion 54B by a slit 55 which extends through the center of the hook portion 54. The hook portion 54 has claws at a distal end portion thereof. The claws 56 of the hook portion 54 are hooked at the edge portion 51 on the second surface 53 of the first overlap margin portion 37. The light-blocking film 33 covers the outer surface of the second case 35 and the outer surface of the cover 28.

According to the third embodiment, the portable computer 11 comprises a metallic housing including the opening part 27 and the first overlap margin portion 37 which neighbors the opening part 27; the resin-made cover 28 which includes the second overlap margin portion 43 lying over the first overlap margin portion 37, and covers the opening part 27; the through-hole portion 38 and the edge portion 51 defining the periphery of the through-hole portion 38, the through-hole portion 38 and the edge portion 51 being provided in the first overlap margin portion 37; the hook portion 54 which is provided in a manner to project from the second overlap margin portion 43, is passed through the through-hole 38, and is hooked at the edge portion 51 on the second surface 53 which is on the side opposite to the first surface 52 of the first overlap margin portion 37, the first surface 52 being opposed to the second overlap margin portion 43; and the light-blocking film 33 covering the outer surface of the housing and the outer surface of the cover 28.

According to this structure, with the use of the hook portion 54, the housing and the cover 28 can be fixed without using welding. It is thus possible to prevent a defective product from occurring due to a failure of welding, and the yield of products can be improved. Since the housing and the cover 28 are covered with the light-blocking film 33, the hook portion 54 is not exposed to the outside and the appearance of the product is good. Moreover, since the connection part between the housing and the cover 28 can be reinforced by the single light-blocking film 33, the strength of attachment of the cover 28 can be improved.

Next, referring to FIG. 8, a fourth embodiment of the electronic apparatus is described. A portable computer 11, which is an example of the electronic apparatus of the fourth embodiment, is different from the portable computer of the third embodiment in that a press-fitting pin 61 is substituted for the hook portion 54. In the other parts, the fourth embodiment is common to the third embodiment. Thus, different parts are mainly described, and a description of the common parts is omitted, with these common parts being denoted by like reference numerals. The portable computer 11 has the same external appearance as in the first embodiment shown in FIG. 1.

The second case 35 includes a first overlap margin portion 37 which is provided at a position neighboring the main body portion 36 and opening portion 27. The first overlap margin portion 37 is provided with a circular through-hole portion 38 and an edge portion 51 which defines the periphery of the through-hole portion 38.

The cover 28 comprises a cover portion 42 which covers the opening part 27; a second overlap margin portion 43 which is so provided as to project from the cover portion 42 and to lie over the first overlap margin portion 37; and the press-fitting pin 61 which is provided in a manner to project from the second overlap margin portion 43. The second overlap margin portion 43 is laid over the first overlap margin portion 37 of the second case 35.

The diameter of the press-fitting pin 61 is set to be equal to, or slightly greater than, the diameter of the through-hole portion 38 of the first overlap margin portion 37. The first overlap margin portion 37 of the second case 35 and the second overlap margin portion 43 of the cover 28 are firmly fixed by the tight fitting of the press-fitting pin 61 in the through-hole 38. The light-blocking film 33 covers the outer surface of the second case 35 and the outer surface of the cover 28.

According to the fourth embodiment, the portable computer 11 comprises a metallic housing including the opening part 27 and the first overlap margin portion 37 which neighbors the opening part 27; the resin-made cover 28 which includes the second overlap margin portion 43 lying over the first overlap margin portion 37, and covers the opening part 27; the through-hole portion 38 and the edge portion 51 defining the periphery of the through-hole portion 38, the through-hole portion 38 and the edge portion 51 being provided in the first overlap margin portion 37; the press-fitting pin 61 which is provided in a manner to project from the second overlap margin portion 43, and is press-fitted in the through-hole 38; and the light-blocking film 33 covering the outer surface of the housing and the outer surface of the cover 28.

According to this structure, the second case 35 and the cover 28 can be fixed with the simple structure using the press-fitting pin 61. It is thus possible to prevent a defective product from occurring due to a failure of a welding work, and the yield of products can be improved. In addition, since the seam between the housing and the cover 28 can be hidden from view by the light-blocking film 33, the appearance of the product can be improved.

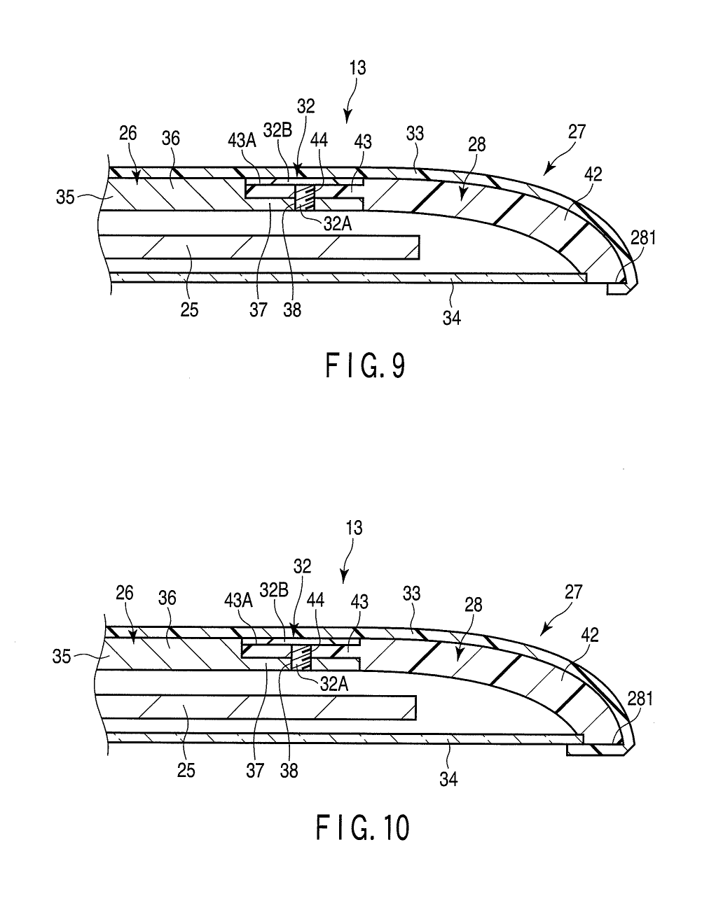

Next, referring to FIG. 9, a fifth embodiment of the electronic apparatus is described. FIG. 9 is a longitudinal cross-sectional view of the display unit of the portable computer according to the fifth embodiment.

A portable computer 11, which is an example of the electronic apparatus of the fifth embodiment, is different from the portable computer of the first embodiment with respect to the region of attachment of the light-blocking film 33 on the display unit 13. In the other parts, the fifth embodiment is common to the first embodiment. Thus, different parts are mainly described, and a description of the common parts is omitted, with these common parts being denoted by like reference numerals. The portable computer 11 has the same external appearance as in the first embodiment shown in FIG. 1.

As shown in FIG. 9, the light-blocking film 33 is attached over the second case 35 and the cover 28. The light-blocking film 33 is attached, for example, by vacuum thermal transfer, to the second case 35 and the cover 28 of the display unit 13.

In the case where the light-blocking film 33 is attached by vacuum thermal transfer to the display unit 13, the light-blocking film 33 can be closely attached up to an end portion 281 of the cover 28. With this structure, the film 33 can surely be closely attached up to the end face of the cover 28, and peeling of the film 33 at the end face can be prevented.

Next, referring to FIG. 10, a sixth embodiment of the electronic apparatus is described. FIG. 10 is a longitudinal cross-sectional view of the display unit of the portable computer according to the sixth embodiment.

A portable computer 11, which is an example of the electronic apparatus of the sixth embodiment, is different from the portable computer of the first embodiment with respect to the region of attachment of the light-blocking film 33 on the display unit 13. In the other parts, the sixth embodiment is common to the first embodiment. Thus, different parts are mainly described, and a description of the common parts is omitted, with these common parts being denoted by like reference numerals. The portable computer 11 has the same external appearance as in the first embodiment shown in FIG. 1.

As shown in FIG. 10, like the fifth embodiment, the light-blocking film 33 is attached, for example, by vacuum thermal transfer, to the display unit 13. The light-blocking film 33 in this embodiment extends over the cover 28 and spans between the first case 34 and the second case 35.

With this structure, the same advantageous effects as with the portable computer 11 of the fifth embodiment can be obtained. Moreover, for example, even in the case where the second case 35 has a shape without corner portions 351, that is, the second case 35 has such a shape that the opening part 27 extends up to the left and right end portions of the second case 35, the cover 28 can be attached to the second case 35 by the film 33, and the cover 28 can be held with high strength of attachment.

In addition, in the present embodiment, since the boundary part between the first case 34 and the second case 35 is hidden from view by the film 33, the appearance of the display unit can be improved, and the range of variations of decoration on the display unit can be increased.

The electronic apparatus in this invention is not limited to the portable computers 11 described in the above embodiments. The invention is applicable to other electronic apparatuses such as mobile phones. Needless to say, the electronic apparatus can be modified without departing from the spirit of the invention.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a metal housing comprising an opening portion and a first overlap margin next to the opening portion;
a cover comprising a resin and comprising a second overlap margin over the first overlap margin, the cover covering the opening portion;
a screw configured to attach the first overlap margin and the second overlap margin; and
a film on and across an outer surface of the metal housing, an outer surface of the cover and a portion of the screw.

2. The electronic apparatus of claim 1, wherein the second overlap margin comprises a recess in the outer surface of the cover, the recess is configured to hold a head portion of the screw.

3. The electronic apparatus of claim 2, wherein the film comprises light-blocking properties.

4. An electronic apparatus comprising:
a metal housing comprising an opening portion and a first overlap margin next to the opening portion;
a cover comprising a resin and comprising a second overlap margin over the first overlap margin, the cover is configured to cover the opening portion;
a through-hole and an edge defining a periphery of the through-hole, the through-hole and the edge being in the first overlap margin;
a hook projecting from the second overlap margin through the through-hole, and configured to be hooked at the edge on a second surface of the first overlap margin, the second surface being on a side opposite to a first surface of the first overlap margin, the first surface being opposite to the second overlap margin; and
a film on and across an outer surface of the metal housing and an outer surface of the cover.

5. The electronic apparatus of claim 4, wherein the film comprises light-blocking properties.

6. An electronic apparatus comprising:
a metal housing comprising an opening portion and a first overlap margin next to the opening portion;
a cover comprising a resin and comprising a second overlap margin over the first overlap margin, the cover configured to cover the opening portion;
a through-hole and an edge defining a periphery of the through-hole, the through-hole and the edge portion being in the first overlap margin;
a press-in pin projecting from the second overlap margin, and is pressed in the through-hole; and
a film on and across an outer surface of the metal housing and an outer surface of the cover.

7. The electronic apparatus of claim 6, wherein the film comprises light-blocking properties.
